(19) United States
(12) Patent Application Publication
(10) Pub. No.: US 2015/0357826 A1
(43) Pub. Date: Dec. 10, 2015

(54) WIRELESS POWER TRANSMISSION AND RECEPTION DEVICE

(71) Applicant: TECHNOVALUE CO., LTD, Seoul (KR)

(72) Inventors: Han-cheol YOO, Seoul (KR); Jong-won KIM, Seongnam-si (KR)

(73) Assignee: TECHNOVALUE CO., LTD, Seoul (KR)

(21) Appl. No.: 14/436,712

(22) PCT Filed: Oct. 18, 2013
(86) PCT No.: PCT/KR2013/009313

§ 371 Date: Jul. 24, 2015

(30) Foreign Application Priority Data
Oct. 18, 2012 (KR) 10-2012-0115741

(51) Int. Cl. H02J 5/00; H02J 7/00; H02J 7/02; H03H 7/38; H02J 17/00

(52) U.S. Cl. CPC H02J 5/005; H03H 7/38; H02J 17/00; H02J 7/025; H02J 7/0052

(57) ABSTRACT

The present disclosure provides a wireless power transmission system. Some embodiments of the present disclosure provide a power collecting device for a wireless power transmission system, including a secondary coil, an impedance matching unit and a rectifier circuit. The secondary coil is configured to generate an induction current from a power supply device for the wireless power transmission system by an electromagnetic field resonating at a predetermined frequency. The impedance matching unit is connected across the secondary coil and is configured to cooperate with the secondary coil for resonating at the predetermined frequency. The rectifier circuit is connected to output terminals of the impedance matching unit and is configured to rectify the induction current in the secondary coil into a direct current.

### TECHNICAL FIELD

The present disclosure relates to a wireless power transmission and reception device, and more particularly, to a power supply device and a power collecting device that increase a power transmission distance by supplying an alternate-current (AC) power to a primary coil of the power supply device and compensate for the transmission efficiency that would be degraded as a secondary coil located at the optimal distance from the primary coil approaches the primary coil.

### BACKGROUND

The statements in this section merely provide background information related to the present disclosure and do not necessarily constitute prior art.

Recently, portable electronic devices have been preferred by users, and have become an essential factor for providing the users with a ubiquitous environment. In addition, various electronic devices with built-in communication capabilities tend to migrate from using wired communication through a cable such as telephone line, network cable, and headphone cable to a wireless communication scheme such as Bluetooth™ and wireless LAN. As the current power supply for the portable electronic devices mainly employs a rechargeable battery, introduction of a wireless charging technology in the battery charging area is epoch-making.

The wireless charging technology can be roughly classified into an electromagnetic induction type, a magnetic resonance type and an electromagnetic wave type.

In the electromagnetic-induction-type charging method, an alternating magnetic field is generated at a transmission side and a current is induced by a change of the magnetic field at a reception side, thus generating energy. In the magnetic-resonance-type charging method, power is transmitted from a transmission side after being converted into a magnetic field capable of resonating and the power is received at a reception side by using a resonant coil having a resonant frequency same as that at the transmission side. In the electromagnetic-wave-type (RF-type) charging method, power energy is converted into a microwave that is advantageous in a wireless transmission, to transmit the energy.

One of the key technical issues in the wireless power transmission technology is to increase the power transmission distance, and for this purpose, the magnetic resonance type is advantageous over the electromagnetic induction type. However, with the increased size of a secondary coil to ensure a predetermined power transmission distance, such technology is difficult to be implemented in a compact reception device such as mobile devices and implanted medical devices.

The long power transmission distance can also be achieved by amplifying a voltage applied to a resonant coil on the power supply side to increase a magnetic field strength generated by the resonant coil. Korean Patent Application Laid-Open No. 2012-0033758 describes a method for amplifying voltage or current applied to a resonant coil (electromagnetic field resonator 412) on the power supply side by arranging a separate coil (electromagnetic field generator 411), such that the voltage applied to the resonant coil is amplified by the transformer between the separate coil and the resonant coil. However, an amplifier based on the transformer disadvantageously increases the size of the components with limited applications depending on the size of the power supply device.

### DISCLOSURE

### Technical Problem

In view of the above aspects, it is an object of the present disclosure to increase the power transmission distance by supplying a high-voltage alternate-current power to a primary coil. It is another object of the present disclosure to compensate for the transmission efficiency that is degraded as a secondary coil located at the optimal distance from the primary coil approaches the primary coil.

### SUMMARY

A power collecting device for a wireless power transmission system, according to some embodiments of the present disclosure, includes a secondary coil configured to generate an induction current from a power supply device for the wireless power transmission system by an electromagnetic field resonating at a predetermined frequency, an impedance matching unit connected across the secondary coil and configured to cooperate with the secondary coil for resonating at the predetermined frequency, and a rectifier circuit connected to output terminals of the impedance matching unit and configured to rectify the induction current in the secondary coil into a direct current (DC).

According to some embodiments, the impedance matching unit includes a first capacitor connected to a side of the secondary coil, and a second capacitor connected to other side of the secondary coil.

According to some embodiments, the first capacitor and the second capacitor are configured to shield an electrical signal induced from the load.

According to some embodiments, the first capacitor and the second capacitor have the same capacitance.

According to some embodiments, the rectifier circuit is a bridge rectifier formed of a bridge connection of four diodes.

According to some embodiments, the power collecting device further includes a smoothing circuit connected in parallel to an output terminal of the rectifier circuit and configured to smooth an output power of the rectifier circuit.

According to some embodiments, the power collecting device further includes a load connected to an output terminal of the rectifier circuit for consuming a rectified power from the rectifier circuit.

According to some embodiments, the load includes a charging circuit configured to charge a secondary battery with the rectified power.

According to another aspect of the present disclosure, a power collecting device for a wireless power transmission system includes a secondary coil configured to generate an induction current from a power supply device for the wireless power transmission system by an electromagnetic field resonating at a predetermined frequency, and an impedance matching unit arranged between the secondary coil and a parasitic impedance on line behind the secondary coil and configured to prevent a change of the predetermined frequency.

According to yet another aspect of the present disclosure, a wireless power transmission system includes a power supply device configured to convert a power into an electromagnetic field capable of resonating and to transmit the power as the electromagnetic field; and a power collecting device including a secondary coil having a resonant frequency same as that of a primary coil included in the power supply device, and configured to receive the power by using the secondary coil, wherein the secondary coil receives the power from the power supply device in an electromagnetic induction scheme when a close approach of the second coil within a predetermined distance from the first coil breaks a electromagnetic resonating field between the primary coil and the secondary coil.

### Advantageous Effects

According to some embodiments of the present disclosure as described above, the high-voltage AC power can be supplied to the primary coil in an efficient manner by generating an AC power from a DC power supply by using a switching element and amplifying the generated AC power by using an LC resonant circuit. In particular, it is advantageous for achieving less power conversion loss by using a passive element in addition to the switching element and for providing a more compact power collecting device.

Further, unlike other amplifiers or transformer-type amplifiers that can be used to supply the high-voltage AC power to the primary coil, the DC voltage supplied from the DC power source can be converted into the AC signal in an efficient manner by using an input signal as a switching signal without amplifying the input signal.

Moreover, the primary coil is coupled with the secondary coil at a specific resonant frequency to transfer the power in the magnetic-resonance-type wireless power transmission system; however, the present disclosure obviates the need for a transformer-type amplifying circuit by amplifying the voltage of the power supplied to the primary coil with the LC resonance. This enables the circuit of the power collecting device to be more compact than the transformer-type amplifying circuit that requires a high volume to achieve high voltage amplification.

Further, by supplying the high-voltage AC power to the primary coil, the electromagnetic field strength generated by the primary coil can be increased, and the power transmission distance can be increased accordingly.

Moreover, by supplying the high-voltage AC power to the primary coil, a dead zone can be eliminated with the power supplied to the secondary coil in an electromagnetic induction scheme by using a strong electromagnetic field generated from the primary coil even when an approach of the secondary coil within the optimal distance of the primary coil breaks the resonance.

Further, by providing a magnetic field strength adjuster configured to adjust the electromagnetic field strength generated by the primary coil, a magnetic field space, i.e., wireless charging space can be formed adaptive to various human/environmental factors.

Moreover, an impedance matching unit, which is connected to each of both the terminals of the secondary coil of the power collecting device, resolves the degraded transmission efficiency inherent in close areas between the power collecting device and the power supply device. At the same time, this arrangement effectively shields noise and other undesirable signals generated from a load.

### BRIEF DESCRIPTION OF DRAWINGS

FIG. 1 is a schematic block diagram of a power supply device in a wireless power transmission system according to some embodiments of the present disclosure.

FIG. 2 is an exemplary circuit diagram of an LC resonant circuit coupled with a switching element, a magnetic field strength adjuster and a primary coil.

FIG. 3 is a graph showing voltage and current waves of the circuit shown in FIG. 2.

FIG. 4 is a schematic block diagram of a power collecting device for a wireless power transmission system according to some embodiments of the present disclosure.

FIG. 5 is a schematic block diagram of a current collector device for a wireless power transmission system according to some embodiments of the present disclosure.

FIG. 6 is an exemplary circuit diagram of the power collecting device shown in FIG. 5.

FIG. 7 is a schematic diagram for illustrating change of mutual inductance depending on the distance between a power supply coil and a power collecting coil.

FIG. 8 is a graph showing change of power transmission efficiency depending on the distance between a power supply coil and a power collecting coil.

REFERENCE NUMERALS

| | |
|---|---|
| 100: power supply device | 110: frequency generator |
| 120: magnetic polarity adjuster | 130: power amplifier |
| 140: switching element | 150: LC resonant inverter |
| 160: magnetic field strength adjuster | 170: primary coil |
| 400: power collecting device | 410: secondary coil |
| 420: impedance matching unit | 430: rectifier circuit |
| 440: smoothing circuit | 450: load |
| 500: power collecting device | 510: secondary coil |
| 520: first impedance matching unit | 525: second impedance matching unit |
| 530: rectifier circuit | 540: smoothing circuit |
| 550: load | 610: secondary coil |
| 620: first capacitor | 625: second capacitor |
| 630: bridge rectifier circuit | 640: smoothing capacitor |
| 650: resistance | 710: power supply device |
| 711: primary coil | 750: power collecting device |
| 751: secondary coil | |

### DETAILED DESCRIPTION

Hereinafter, some embodiments of the present disclosure will be described in detail with reference to the accompanying drawings. In the following description, like reference numerals designate like elements although the elements are shown in different drawings. Further, in the following description of the at least one embodiment, a detailed description of known functions and configurations incorporated herein will be omitted for the purpose of clarity and for brevity.

Additionally, various terms such as first, second, A, B, (a), (b), etc., are used solely for the purpose of differentiating one component from the other but not to imply or suggest the substances, order or sequence of the components. It will be understood that the terms “comprises” and/or “comprising,” or “includes” and/or “including” when used in this specification, specify the presence of one or more other components, but do not preclude the presence or addition of one or more other components unless defined to the contrary. If a component were described as ‘connected’, ‘coupled’, or ‘linked’ to another component, they may mean the components are not only directly ‘connected’, ‘coupled’, or ‘linked’ but also are indirectly ‘connected’, ‘coupled’, or ‘linked’ via one or more additional components.

A magnetic-resonance-type wireless power transmission system includes a power supply device that converts a power into a resonant electromagnetic field and transmits the resonant electromagnetic field and a power collecting device that receives the power by using a resonant coil having a resonant frequency same as that of the power-supply-side resonant coil.

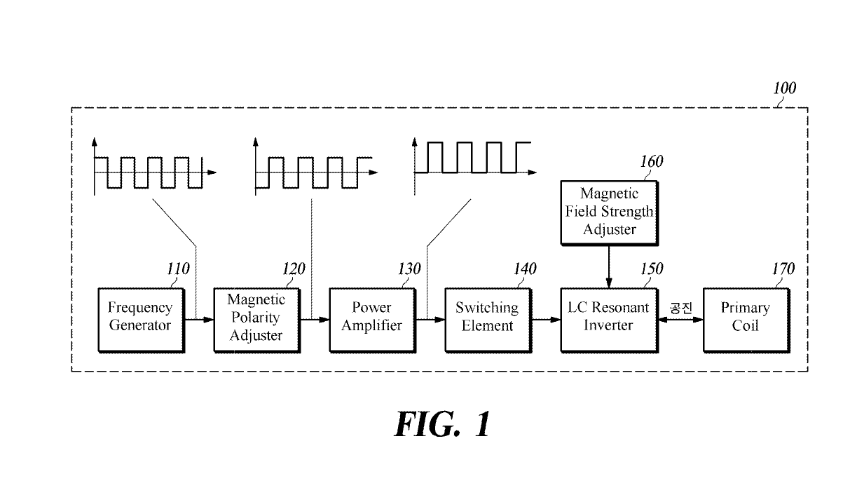

FIG. 1 is a block diagram of a power supply device in a wireless power transmission system according to some embodiments of the present disclosure.

As shown in FIG. 1, in some embodiments, a power supply device 100 includes a power supply unit (not shown), a frequency generator 110, a power amplifier 130, a switching element 140, an LC resonant inverter 150, a magnetic field strength adjuster 160 and a primary coil 170.

The power supply unit (not shown) supplies a power to each component of the power supply device 100. Specifically, the power supply unit receives power supplied thereto, converts the power to a voltage required for each component of the power supply device 100, and supplies the converted power to each component of the power supply device 100.

The frequency generator 110 generates a power carrier signal having a predetermined frequency required to transmit the power.

The power amplifier 130 adjusts a signal level of the power carrier signal applied to the switching element 140. It is preferred that the input power carrier signal be biased to be close to a pinch-off voltage of the switching element 140.

The switching element 140 operates as an ON-OFF switch that is driven by the power carrier signal, which is turned ON when the level of the power carrier signal is High and turned OFF when the level of the power carrier signal is Low. In some embodiments, the switching element 140 includes a BJT, a MOSFET, or a MESFET.

The LC resonant inverter 150 generates an AC power from a DC power by the switching operation of the switching element 140, and converts the generated AC power into a high-voltage AC power by forming an LC resonant circuit with the primary coil 170. The resonant frequency of the LC resonant circuit is same as an oscillation frequency of the power carrier signal generated by the frequency generator 110.

The magnetic field strength adjuster 160 adjusts the electromagnetic field strength generated from the primary coil side by changing impedance of the LC resonant inverter 150 viewed from the primary coil side. In other words, the electromagnetic field strength generated from the primary coil 170 is adjusted by adjusting a magnitude of the AC voltage amplified at the primary coil 170, and eventually the power transmission distance can be adjusted. The impedance of a power transmission channel between the power supply device 100 and the power collecting device can be changed depending on the environment in which the power supply device 100 is disposed, and the required power transmission distance can be changed depending on user and installation place of the power supply device. Therefore, by adjusting the electromagnetic field strength generated from the primary coil 170, the magnetic field space, i.e., the wireless charging space can be formed in an efficient manner adaptive to various human/environmental factors.

The primary coil 170 is coupled with a secondary coil of the power collecting device with the resonant frequency, and transmits a resonant power to the secondary coil. In other words, the primary coil 170 supplied with a high-frequency power by the LC resonant inverter 150 forms an electromagnetic field that oscillates at the resonant frequency. Accordingly, the energy supplied to the primary coil 170 exists near the primary coil 170 as electric field and magnetic field that oscillate at the resonant frequency. At this time, if the secondary coil is placed near the primary coil 170, as the resonant frequency of the secondary coil matches the resonant frequency of the magnetic field, an energy transmission path is formed between the primary coil 170 and the secondary coil, and the power is transmitted to the power collecting device side.

In some embodiments, the power supply device 100 further includes a magnetic polarity adjuster 120. The magnetic polarity adjuster 120 adjusts a polarity of the electromagnetic field generated from the primary coil 170 by inverting a phase of the power carrier signal applied to the switching element 140. The magnetic polarity adjuster 120 can be implemented with a simple inverter which can be placed in a stage next to the frequency generator 110 or the power amplifier 130.

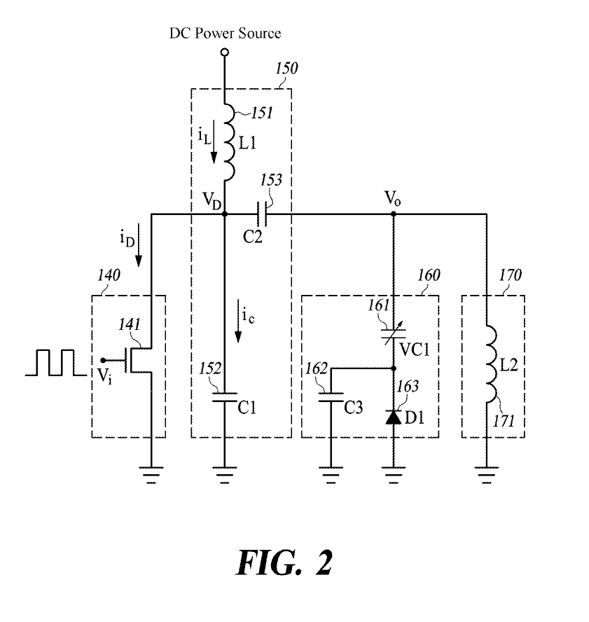

With reference to FIG. 2, the following describes the operations of the switching element 140, the LC resonant inverter 150, the magnetic field strength adjuster 160 and the primary coil 170.

FIG. 2 is an exemplary circuit diagram of an LC resonant circuit coupled with a switching element, a magnetic field strength adjuster, and a primary coil.

A case where a MOSFET 141 is used as the switching element 140 is shown In FIG. 2.

The power carrier signal is applied to a gate terminal of the MOSFET 141, and controls ON-OFF state of the MOSFET 141. The input power carrier signal is biased to be close to a pinch-off voltage of the MOSFET 141. A drain terminal of the MOSFET 141 is connected to a DC power source via an inductor L1 151, and a source terminal of the MOSFET 141 is connected to the ground.

When the MOSFET 141 is in the ON state, the MOSFET 141 works as a short circuit with respect to the ground, and zeros a node voltage V_{D} on the drain side.

When the state of the MOSFET 141 is changed from the ON state to the OFF state, the node voltage V_{D} on the drain side is increased. This is because a back electromotive force inducted in the inductor L1 151 suppresses the current change, which causes the current to continuously flow from the inductor L1 151 even after the MOSFET 141 is turned OFF, and hence charges are accumulated in a capacitor C1 152. After a predetermined time, the charges in the capacitor C1 152 begin to flow toward a capacitor C2 153, which causes the node voltage V_{D} on the drain side to stop increasing but rather to decrease. The node voltage V_{D} on the drain side returns to zero before the MOSFET 141 is in the ON state again.

The capacitor C2 153 and a primary coil L2 171 constitute an LC serial resonant circuit which operates as a resonant circuit in which the energy is exchanged therebetween. In other words, the node voltage V_{D} on the drain side is amplified by the LC resonant circuit formed by interconnecting the capacitor C2 153 and the primary coil L2 171, and eventually a considerably high voltage is applied to the primary coil L2 171. The resonant frequency of the LC resonant circuit matches the oscillation frequency of the power carrier signal generated from the frequency generator, and hence the power transmitted from the primary coil L2 171 to the secondary coil that is electromagnetically coupled with the primary coil L2 171 is continuously supplied from the DC power source connected to the inductor L1 151.

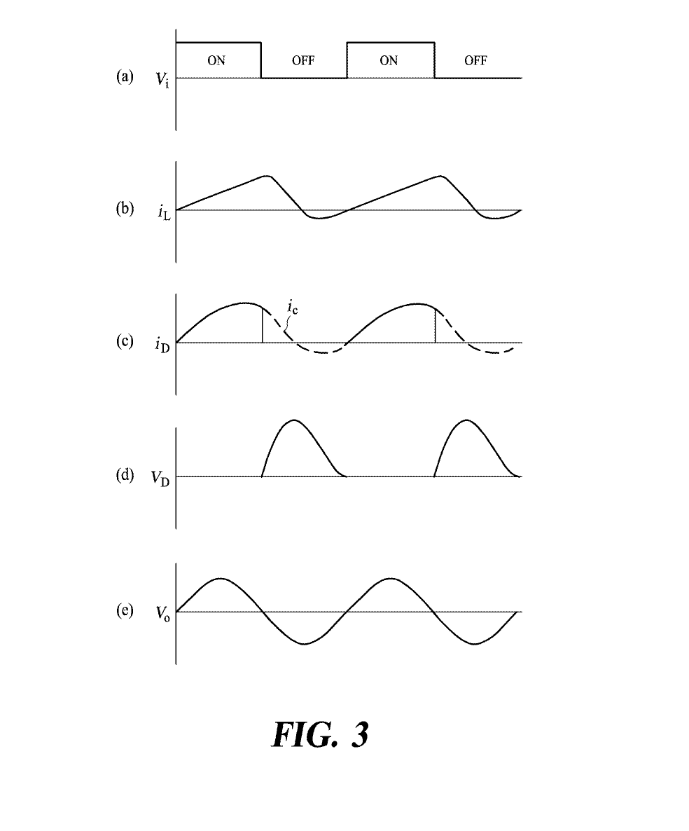

Referring to FIG. 3, the following describes two-cycle values of a gate terminal voltage Vᵢ, a current i_{L} flowing through the inductor L1 151, a current i_{D} flowing through the drain terminal, a drain terminal voltage V_{D}, a current i_{C} flowing through the capacitor C1 152, and a voltage V_{O} across the primary coil L2 171.

FIG. 3 is a graph showing voltage and current waves of the circuit shown in FIG. 2.

As shown in FIG. 3, while the MOSFET 141 is in the ON state, the drain terminal voltage V_{D} of the MOSFET 141 is zero. When the voltage Vᵢ applied to the gate becomes a threshold value of the MOSFET 141 or lower, the MOSFET 141 becomes cut-off, and the drain terminal voltage V_{D} begins to increase. When the current i_{C} flowing through the capacitor C1 152 becomes zero, the drain terminal voltage V_{D} reaches a peak. When the current flowing through the capacitor C1 152 becomes a negative value, the drain terminal voltage V_{D} begins to decrease. Before the MOSFET 141 returns to the ON state, the drain terminal voltage V_{D} reaches zero. When the drain terminal voltage V_{D} is applied to the LC resonant circuit that only passes the fundamental frequency of the drain voltage wave, a voltage V_{O} having a wave shown in FIG. 3 is generated.

A magnetic field strength adjuster 240 is connected to a contact of the capacitor C2 153 and the primary coil L2 171 that constitute the serial resonant circuit, and is configured to control the strength of the electromagnetic field emitted by the primary coil L2 171 by changing the impedance of the LC resonant inverter 150 viewed from the primary coil L2 171 side. In the example shown in FIG. 2, the magnetic field strength adjuster 240 includes a variable capacitor VC1 161, and a capacitor C3 162 and a diode D1 163 connected in parallel between the variable capacitor VC1 161 and the ground. When the capacitor C2 153 and the primary coil L2 171 resonate with a resonant frequency substantially the same as the oscillation frequency of the power carrier signal, even a slight change of the capacitance of the variable capacitor VC1 161 can exert a considerable influence on the resonant voltage.

The diode D1 163 is configured to function as a protective diode for preventing circuit damage due to an external surge voltage or the like.

In this manner, in some embodiments, the AC power is generated from the DC power source and amplified by using the LC resonant circuit, and hence, ideally, there is no power loss due to the power conversion. However, in practice, there is a slight power conversion loss due to the internal resistance of a switching element.

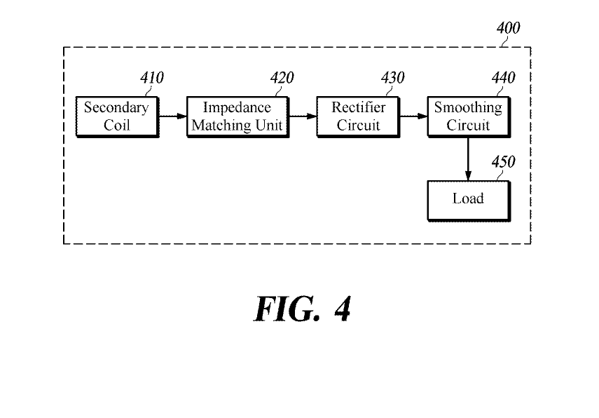

FIG. 4 is a block diagram of a power collecting device for a wireless power transmission system according to some embodiments of the present disclosure.

As shown in FIG. 4, a power collecting device 400 includes a secondary coil 410, an impedance matching unit 420, a rectifier circuit 430, a smoothing circuit 440 and a load 450.

The secondary coil 410 has a resonant frequency that matches the resonant frequency of the magnetic field formed by the primary coil of the power supply device, thus forming a resonance channel with the primary coil to receive the power.

The impedance matching unit 420 is connected to the secondary coil 410 to compensate for the impedance, thus adjusting the resonant frequency of the secondary coil, and at the same time, shields a parasitic impedance or the like from behind the impedance matching unit 420 of the secondary coil 410 in calculating an input impedance of the primary coil.

The rectifier circuit 430 rectifies an AC current generated from the secondary coil 410 to a DC current. The rectifier circuit 430 can be implemented with at least one of various rectifier circuits including a half-wave rectifier circuit, a full-wave rectifier circuit, a bridge rectifier circuit and a voltage-multiplier rectifier circuit.

The smoothing circuit 440 smoothes an output voltage rectified by the rectifier circuit 430. Specifically, the smoothing circuit 440 is connected in parallel to an output terminal of the rectifier circuit 430, and smoothes the output voltage of the rectifier circuit 430.

The load 450 consumes the rectified DC power. Specifically, the load 450 receives the power that is converted into the DC power by the rectifier circuit 430 and the smoothing circuit 440, and performs an intended function of a power receiving device. In some embodiments, the load 450 includes a charging circuit and a secondary battery, and is configured to charge the secondary battery by using the rectified DC power. In particular, the charging circuit includes a protective circuit such as an overvoltage and overcurrent preventing circuit, a temperature detecting circuit, and a charging management module for collecting and processing information on the charging status of the secondary battery or the like.

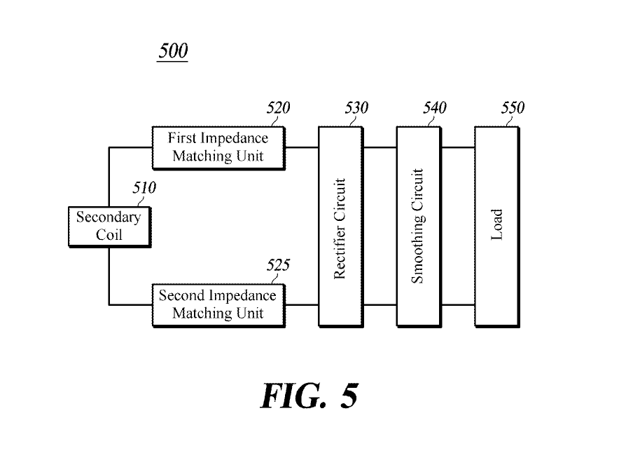

FIG. 5 is a block diagram of a current collector device for a wireless power transmission system according to some embodiments of the present disclosure.

As shown in FIG. 5, in some embodiments, impedance matching units are respectively connected to both terminals of a secondary coil 510 in series. Specifically, a first impedance matching unit 520 is connected to a first terminal of the secondary coil 510, and a second impedance matching unit 525 is connected to a second terminal of the secondary coil 510.

The total capacitive reactance of the two impedance matching units 520 and 525 and an inductive reactance of the secondary coil 510 match each other, and hence the two impedance matching units 520 and 525 and the secondary coil 510 resonate at the same frequency as the resonant frequency of the power supply device. The electric field and the magnetic field that oscillate at the resonant frequency near the primary coil generate a resonance with the secondary coil that resonates at the same frequency.

A rectifier circuit 530 is connected to output terminals of the first impedance matching unit 520 and the second impedance matching unit 525. A smoothing circuit 540 is connected to an output terminal of the rectifier circuit 530 to smooth the rectified power, and a load 550 is connected to an output terminal of the smoothing circuit 540, so that the rectified power is supplied to the load 550.

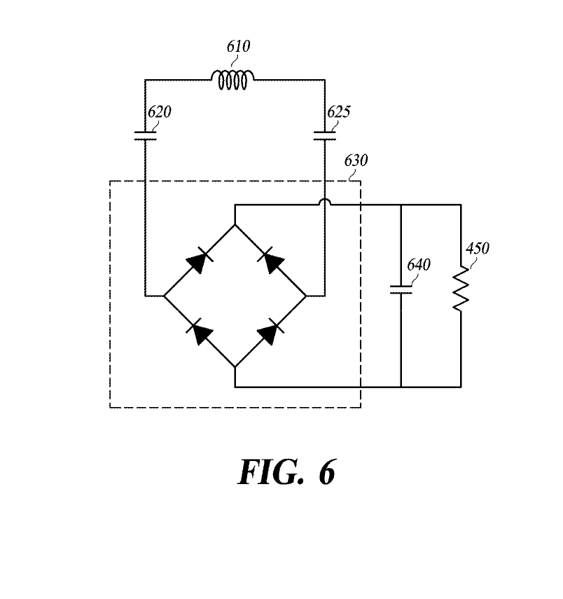

FIG. 6 is an exemplary circuit diagram of the power collecting device shown in FIG. 5.

In the example shown in FIG. 6, a first side of a first capacitor 620 is connected to a first side of a secondary coil 610, and a first side of a second capacitor 625 is connected to a second side of the secondary coil 610. The rectifier circuit 530 shown in FIG. 5 is implemented as a bridge rectifier circuit 630 that is a full-wave rectifier circuit including four diodes, and a second side of the first capacitor 620 and a second side of the second capacitor 625 are connected to an input terminal of the bridge rectifier circuit 630. The smoothing circuit 540 and the load 550 shown in FIG. 5 are simplified as a smoothing capacitor 640 and a resistor 650.

In this manner, in some embodiments, by respectively connecting the first capacitor 620 and the second capacitor 625 to both terminals of the secondary coil 610, a non-periodic repulsive signal generated from the load side can be effectively shielded, compared to the case where the capacitor for performing the impedance matching function is connected to only one side of the secondary coil 610, and at the same time, a parasitic impedance or the like at the subsequent stage of the impedance matching unit of the secondary coil is shielded in calculating an input impedance of the primary coil.

The capacitors perform a function of transferring the AC component exclusively without transferring the DC component from the secondary coil 610 to the subsequent stage. The circuit shown in FIG. 6 is a mere example of the embodiments of the present disclosure, and hence the present disclosure is not limited to this, but includes all impedance matching units having a function of preventing a change of the resonant frequency due to the parasitic impedance.

In some embodiments, the first capacitor 620 and the second capacitor 625 have the same capacitance, and in this case, voltages having different phases from each other are respectively applied to the capacitors 620 and 625, and as a result, a virtually smoothed voltage corresponding to twice the voltage across each of the capacitors 620 and 625 is applied to both terminals of the smoothing capacitor 640 to which the voltage rectified by the bridge rectifier circuit 530 is supposed to be applied.

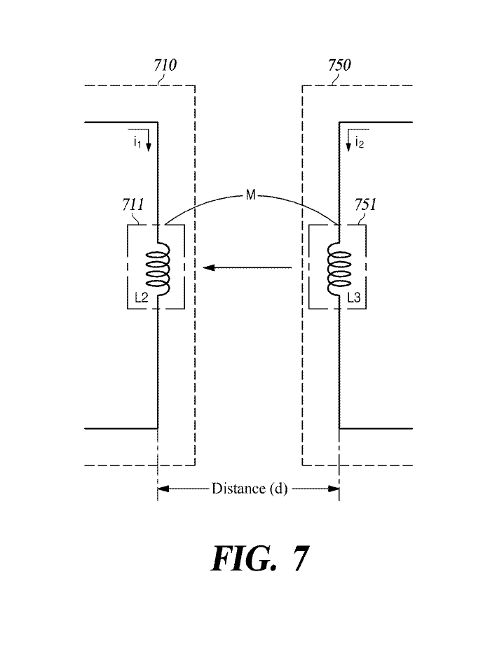

FIG. 7 is a schematic diagram for illustrating change of mutual inductance with change of distance between a power supply coil and a power collecting coil.

As described above, the energy supplied to a primary coil 711 exists as the electric field and the magnetic field that oscillates with the resonant frequency near the primary coil 711. At this time, if a secondary coil 751 is placed near the primary coil 711, as the resonant frequency of the secondary coil 751 matches the resonant frequency of the magnetic field, an energy transmission path is formed between the primary coil 711 and the secondary coil 751, and the power is transmitted to the power collecting device side.

When the primary coil 711 and the secondary coil 751 are coupled with each other at the same resonant frequency in the above manner, if a power collecting device 750 is moved or its direction is changed, a mutual inductance M between the primary coil 711 and the secondary coil 751 is changed. For this reason, when the distance is increased or decreased from the optimal distance that provides the highest transmission efficiency, the transmission efficiency is sharply degraded.

For example, when the two coils 711 and 751 approach each other from the optimal distance that provides the highest transmission efficiency, the mutual inductance M between the two coils 711 and 751 is increased. The resonant frequency changed due to the increase of the mutual inductance M does no longer match the power source frequency supplied to the primary coil 711. Consequently, the intensity of the current supplied to the primary coil 711 is sharply decreased, and the resonance between the primary coil 711 and the secondary coil 751 is broken. One of the parameters for determining the transmission efficiency, k, is proportional to the mutual inductance M, so that the transmission efficiency should be increased as the two coils 711 and 751 approach each other; however, the transmission efficiency is sharply decreased. A zone in which the transmission efficiency is sharply decreased within a predetermined distance in the above manner is referred to as a dead zone. This is the difference from the electromagnetic induction type.

A method for compensating the change of the mutual inductance includes changing the power source frequency according to the change of the resonant frequency due to the change of the mutual inductance, canceling the change of the mutual inductance by adjusting inductance or capacitance of a power supply device 710, or the like.

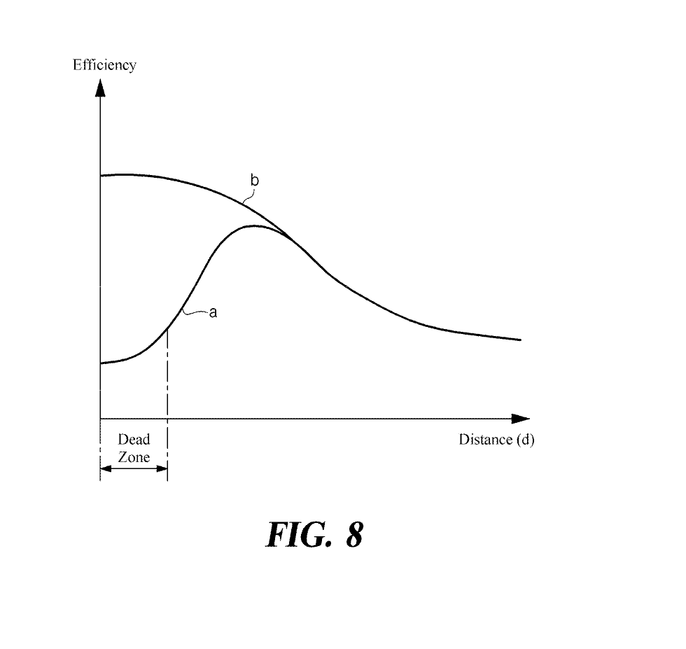

FIG. 8 is a graph showing change of power transmission efficiency with change of distance between a power supply coil and a power collecting coil.

A curve a in the graph shown in FIG. 8 indicates a change of the power transmission efficiency depending on the distance between the power supply coil and the power collecting coil generally obtained when the change of impedance with the change of the position of the secondary coil is not compensated. A curve b indicates the power transmission efficiency according to some embodiments of the present disclosure, in which the intensity of the induction current induced to the secondary coil 410 is increased and the power transmission efficiency is increased as the distance is decreased. This effect is caused by the following reasons.

Firstly, in the wireless power transmission system according to some embodiments of the present disclosure, a considerably high voltage is applied to the power supply device, and hence a considerably strong electromagnetic field is formed in the near field of the primary coil. Even when the resonance is broken due to the close approach of the secondary coil within the optimal distance of the primary coil in such a near field, the voltage is induced to the secondary coil in the electromagnetic induction scheme from the strong electromagnetic field near the primary coil. This prevents the transmission efficiency in the dead zone from being degraded.

Secondly, in the wireless power transmission system according to some embodiments of the present disclosure, the impedance matching units are respectively disposed at both terminals of the secondary coil of the power collecting device, and hence the inductive reactance of the secondary coil are canceled via the two impedance matching units such that the resonant frequency matches that of the power collecting device, and at the same time, resonant currents having a phase difference of 180° respectively flow to the impedance matching units at both terminals. Therefore, twice the voltage is applied to the output terminal of the rectifier circuit, compared to the case where the impedance matching unit is disposed on only one side of the secondary coil. As a result, even when the transmission efficiency is decreased due to the close approach of the primary coil and the secondary coil within the optimal distance, a considerable amount of voltage is supplied to the load of the secondary coil.

Thirdly, in the wireless power transmission system according to some embodiments of the present disclosure, the impedance matching unit is disposed behind the secondary coil of the power collecting device, and hence excluding the influence of the parasitic impedance on the change of the whole impedance due to the change of the distance between the power supply device and the power collecting device. The parasitic impedance at this time means impedance caused by the rectifier circuit, the smoothing circuit, the load and the like.

Each of the resonant frequencies of the power supply device and the power collecting device can be changed in association with the whole impedance of each device. Therefore, the change of the distance between the power supply device and the power collecting device causes the change of the whole impedance of each of the power supply device and the power collecting device, which may lead to a mismatch of the resonant frequencies between the power supply device and the power collecting device. The impedance matching unit according to some embodiments of the present disclosure excludes the parasitic impedance from among the factors that change the whole impedance caused by the above-mentioned change of the distance, thus preventing the mismatch of the resonant frequencies due to the change of the whole impedance. Accordingly, the impedance mismatching can be prevented from being increased in the near distance between the two devices where the coupling of the primary coil and the secondary coil is strong.

Although exemplary embodiments of the present disclosure have been described for illustrative purposes, those skilled in the art will appreciate that various modifications, additions and substitutions are possible, without departing from the spirit and scope of the claimed invention. Accordingly, one of ordinary skill would understand the scope of the claimed invention is not to be limited by the explicitly described above embodiments but by the claims and equivalents thereof.

### CROSS-REFERENCE TO RELATED APPLICATION

If applicable, this application claims priority under 35 U.S.C. §119(a) of Patent Application No. 10-2012-0115741, filed on Oct. 18, 2012 in Korea, the entire content of which is incorporated herein by reference. In addition, this non-provisional application claims priority in countries, other than the U.S., with the same reason based on the Korean patent application, the entire content of which is hereby incorporated by reference.

1. A power collecting device for a wireless power transmission system, the power collecting device comprising:
a secondary coil configured to generate an induction current from a power supply device for the wireless power transmission system by an electromagnetic field resonating at a predetermined frequency;
an impedance matching unit connected across the secondary coil and configured to cooperate with the secondary coil for resonating at the predetermined frequency; and
a rectifier circuit connected to output terminals of the impedance matching unit and configured to rectify the induction current in the secondary coil into a direct current.

2. The power collecting device according to claim 1, wherein the impedance matching unit includes:
a first capacitor connected to a side of the secondary coil, and
a second capacitor connected to other side of the secondary coil.

3. The power collecting device according to claim 2, wherein the first capacitor and the second capacitor are configured to shield parasitic impedances from behind the first capacitor and the second capacitor in calculating an input impedance of the power supply device for the wireless power transmission system.

4. The power collecting device according to claim 2, wherein the first capacitor and the second capacitor have the same capacitance.

5. The power collecting device according to claim 1, wherein the rectifier circuit is a bridge rectifier comprising a bridge connection of four diodes.

6. The power collecting device according to claim 1, further comprising a smoothing circuit connected in parallel to an output terminal of the rectifier circuit and configured to smooth an output power of the rectifier circuit.

7. The power collecting device according to claim 1, further comprising a load connected to an output terminal of the rectifier circuit for consuming a rectified power from the rectifier circuit.

8. The power collecting device according to claim 7, wherein the load includes a charging circuit configured to charge a secondary battery with the rectified power.

9. A power collecting device for a wireless power transmission system, the power collecting device comprising:
a secondary coil configured to generate an induction current from a power supply device for the wireless power transmission system by an electromagnetic field resonating at a predetermined frequency; and
an impedance matching unit arranged between the secondary coil and a parasitic impedance on line behind the secondary coil and configured to prevent a change of the predetermined frequency.

10. A wireless power transmission system, comprising:
a power supply device configured to convert a power into an electromagnetic field capable of resonating and to transmit the power as the electromagnetic field; and
a power collecting device including a secondary coil having a resonant frequency same as that of a primary coil included in the power supply device, and configured to receive the power by using the secondary coil, wherein
the secondary coil receives the power from the power supply device in an electromagnetic induction scheme when a close approach of the second coil within a predetermined distance from the first coil breaks an electromagnetic resonating field between the primary coil and the secondary coil.
